(19) United States
(12) Patent Application Publication
(10) Pub. No.: US 2003/0151422 A1
(43) Pub. Date: Aug. 14, 2003

(54) Method for burn-in testing

(76) Inventors: Thomas S. Barnett, Burlington, VT (US); Matthew S. Grady, Burlington, VT (US); Kathleen G. Purdy, Richmond, VT (US)

Correspondence Address: IBM MICROELECTRONICS, INTELLECTUAL PROPERTY LAW, 1000 RIVER STREET, 972 E, ESSEX JUNCTION, VT, 05452, US

(21) Appl. No.: 10/248,126

(22) Filed: Dec. 19, 2002

Related U.S. Application Data
(60) Provisional application No. 60/344,209, filed on Dec. 26, 2001.

(51) Int. Cl. G01R 31/26

(52) U.S. Cl. 324/765

(57) ABSTRACT

Method for burn-in testing of a wafer having a plurality of dies where the reliability of the fail rate is matched to meet a predetermined criteria. This is accomplished by selecting a subset of dies to be tested and tests are used to weed out the highest number of failures.

This invention claims priority based on Provisional Patent Application No. 60/344,209, filed on Dec. 26, 2001.

### BACKGROUND OF THE INVENTION

1. Field of the Invention

This invention relates generally to testing semiconductor devices and more particularly to statistical analysis applied to burn-in testing techniques.

2. Background

Semiconductor manufacturers routinely test integrated circuit product in wafer and/or packaged form to screen out defects and ensure quality levels shipped to the customer/consumer. Even after such tests are performed, however, a certain quantity of parts shipped will eventually fail to function after running in a use condition for some period of time. Such parts are said to possess ‘reliability defects’; i.e. defects that are not apparent until after the parts have been ‘aged’ for some period of time. Many semiconductor manufacturers therefore use an acceleration technique called ‘burn in’ as part of their production test flow. Burn-in generally consists of exposing the part to extremes of voltage and temperature (usually high voltage and high temperature), and possibly operating the part while at these extremes. An extensive theory and practice exists that models the equivalent number of hours of use a part is ‘aged’ as a function of having been subjected to burn in. As a result, semiconductor manufacturers can use burn-in to artificially age and screen out many/most reliability defects in their products before shipping the parts to the consumer, and the consumer will then see a lower quantity of reliability fails.

### SUMMARY OF THE INVENTION

The problem with burn-in process is that the number of parts actually possessing a reliability defect in a typical mature semiconductor process is a very small fraction of the total number of otherwise good parts (usually less than 1%, and sometimes dramatically less). On most of the product, burn-in is therefore not useful. The cost of burn-in is also becoming a larger percentage of the overall production cost as semiconductor process technology advances. This cost is increasing because newer semiconductor process technologies inherently make parts that consume more electrical power when operated at typical burn-in conditions. The problem of providing this power and maintaining the temperature of the integrated circuit makes the burn-in system more complex and costly. Therefore, methods are needed to avoid burn-in on as many parts as possible while still maintaining reasonable outgoing reliability levels.

Accordingly an object of this invention is to improve the method of separating parts into categories of different reliability levels.

Another object is to use the test information collected when the parts are first tested in wafer form before packaging.

A further object is to develop a method to reduce burn-in requirements and improve reliability.

### BRIEF DESCRIPTION OF THE DRAWINGS

FIG. 1 is a table which illustrates reliability fail probability.

FIG. 2 is a graph which illustrates memory reliability fail probability.

FIG. 3 is a graph which illustrates distribution of I ddQ measurements at a given setting.

FIG. 4 is a table which table which illustrates local region yield analysis using a bin fail ratio.

FIG. 5 is a table which illustrates a failure rate by chip choice.

FIG. 6 is a table which illustrates a high reliability product.

### DETAILED DESCRIPTION OF PREFERRED EMBODIMENT OF THE INVENTION

The present invention deals with methods of separating parts into categories of different reliability levels (preferably using information when the parts are first tested in wafer form before packaging), and the application of such methods to reduction of burn-in requirements or reliability improvement. The four techniques to be used for improving the process are as follows:

1) Skip Plan—where a subset of the overall population (the subset most likely to fail) undergoes burn-in and the rest skip burn-in;

2) Picking for High Reliability—where the subset of parts least likely to fail is used for the highest reliability application, and the remainder are used for a lower reliability application;

3) Maverick Screen Improvement—where good chips from wafers designated for scrap are ‘rescued’ because they have low risk indications for reliability failure;

4) Burn-in Optimization—where a manufacturer has very limited burn-in capability and would like to answer the question, “If I can only burn-in X% of the parts, which parts should I select?

Several techniques for separating or binning parts into buckets that have differing degrees of reliability have been suggested. A summary of some of these techniques follows:

Once parts are separated into groups of different reliability by any of the above mentioned means, several applications are possible. Assuming that through some type of study of burn-in or field fail results, a determination was made of the overall population reliability fail rate. Such a rate is commonly referred to in units of ‘fails in time’ (fits), or parts per million defective per thousand hours of use. Typically a FIT rate can be given for a population in the cases of:

no burn-in(0% burn in)

100% burn-in at a specific stress condition (usually voltage and temperature)

Given the above, the following four mathematical for binning parts may be considered for selection of these different applications may be applied are identified as skip plan, picking, materials screen, and burn-in optimization as follows:

1) Skip Plan

If 100% burn-in gives a lower than required reliability fail rate for the customer, but 0% burn-in gives too high a fail rate, then a skip plan is appropriate. One chooses as few of the worst reliability bins as possible to ‘weed out’ the highest number of fails as possible, until the required outgoing fail rate is met.

2) Picking for High Reliability Applications

Sometimes an integrated circuit product is used in more than one application, and these applications have different reliability requirements. The application with the requirement of the best reliability will require more burn-in or screening to get the parts to the lower fail rate. An alternative is to purposely choose the parts binned as ‘most reliable’ for the high reliability application, and use the remainder for the low reliability application.

3) Maverick Screen Improvement

‘Whole wafer’ maverick screen is used by a manufacturer in various forms. The manufacturer could instead use individual chip dispositioning based on reliability binning to get improved overall quality levels while minimizing scrap.

4) Burn-in Optimization

This may be used by a semiconductor manufacturer which is in the position of simply wanting to improve their outgoing quality level, where a very limited amount of burn-in capacity is available, then burn-in optimization is an appropriate application. This allows the manufacturer to answer the question, “If I can only burn-in X% of the parts, which parts should I burn-in to get the largest benefit?” The worst reliability bins are chosen until the capacity is consumed.

Some manufacturers sometimes make random samples of parts to route to burn-in to get random detection of reliability defects without burning in the entire population. The advantage of the present invention is that the parts that or more or less likely to fail (as compared with a random sample of the entire population) are identified, so the burn-in done is more effective.

Techniques for separating or binning parts into buckets that have differing degrees of reliability are outlined below:

1) Local Region Yield:

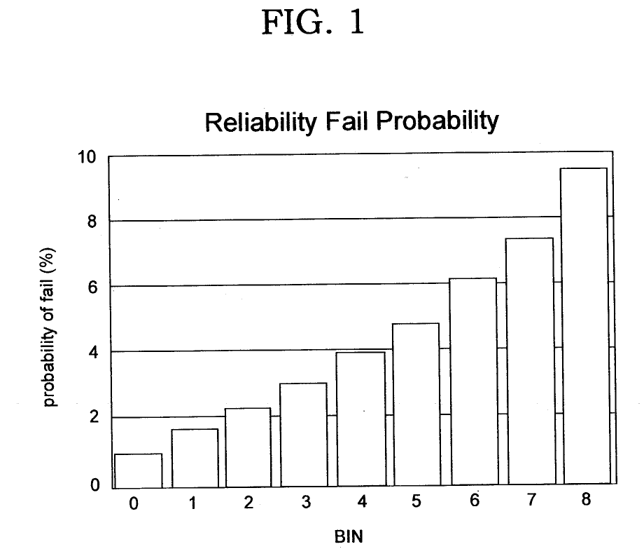

The local region yield method involves computing the count of failures of the eight chips surrounding a given die on a wafer. Each die will therefore be classified into one of eight categories (0 bad neighbors, 1 bad neighbors, etc. up to 8 bad neighbors). Depending on the amount of clustering of defects on a wafer and the average number of ‘killer’ (as opposed to ‘latent’, or reliability) defects on a wafer, the die in each bin will have a different probability of possessing a reliability defect. Die with 0 bad neighbors will have the lowest probability of having a reliability defect, while die with 8 bad neighbors will have the greatest probability of reliability failure. An illustration of this concept is shown in FIG. 1.

One can see that die in bin 8 are more than 9 times likely to contain a reliability defect as die in bin 0. An analytic mathematical model may be established to determine a fail rate relationship.

2) Repair/Defect Count in Memory ICs:

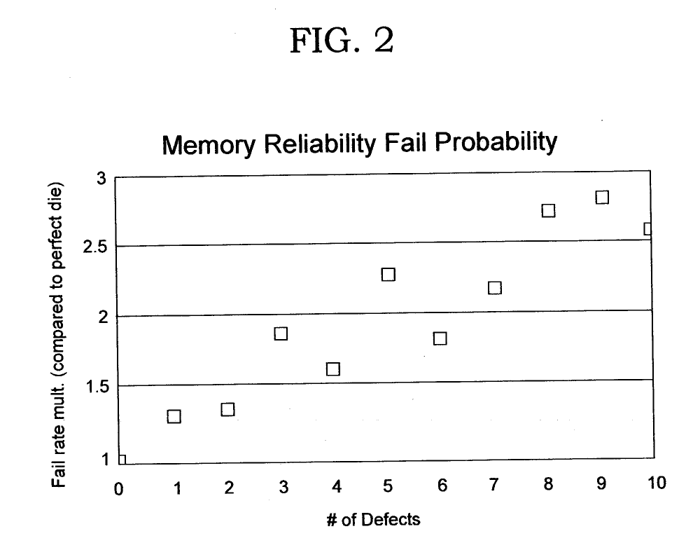

Memory integrated circuits often feature redundancy that can be invoked to do a ‘repair’ of a faulty area of the chip. Such redundancy is used to increase the total number of yielding devices on a wafer. A mathematically model of the reliability of a particular chip is expected to be directly proportional to the number of killer defects the die possesses (and therefore repairs). Chips that are ‘perfect’ and require no repair will have the best reliability. As the number of repairs/defects increases, the reliability of the part decreases. An illustration of this is shown in FIG. 2.: As indicated in FIG. 2 which is based on measured burn-in fails on a memory product. The slope of the line is a function of the degree of defect clustering on the wafer. The plot agrees with the a mathematical model.

3) Empirical Analysis of Wafer Yield:

A number of possible sort indicators from chips during wafer test that may best predict whether another die will pass or fail. These possible indicators are then used as inputs to a common statistical inference technique (such as multiple linear regression or partial least squares) to make an empirical correlation between whether a die yields or not. The yield of immediately neighboring die is most influential on the die in question, while the yield of the same position on other wafers in the same lot also has some influence. The weight of these factors derive a score, which determines likelihood of yielding, called the unit level predicted yield (ULPY).

An empirical demonstration that the die with high ULPY are less likely to possess reliability defects, while die with low ULPY are more likely to possess reliability defects. In effect, the result is separation of good die into categories with different probabilities of possessing reliability defects. The difference between this technique and ‘local region yield’ is that the former is empirical while the latter is analytical. The conclusions are very similar.

4) Wafer Screens and Empirical Analysis of Lot Yield:

It can be empirically demonstrated that a linear correlation may be made between the parts per million rate of ‘field returns’ (parts that fail after its use for some period of time, i.e. reliability defects) and the lot yield the returned part came from. Parts from lower yielding lots were more likely to become field returns than parts from higher yielding lots. The impact of adding additional ‘harder’ tests at the wafer test step was shown to reduce the parts per million rate of field returns. After the enhanced wafer screens were added, the field fail rate decreased. One therefore could use extended wafer screens to reduce the overall reliability fail rate, and then separate parts by lot yield to have parts with varying degrees of reliability.

5) Parametric Outlier Classification:

Many types of tests that can be done on integrated circuits yield not just a pass/fail result, but rather a numeric measurement that gives a parametric quantification of the device's behavior. Such parametric tests include (but are not limited to):

I_{ddQ} testing (at one or more power supply settings, or temperatures, or pattern conditions, etc.)

Power supply range of operation in different functional modes

Frequency range of operation in different functional modes

Temperature range of operation in different functional modes

Etc.

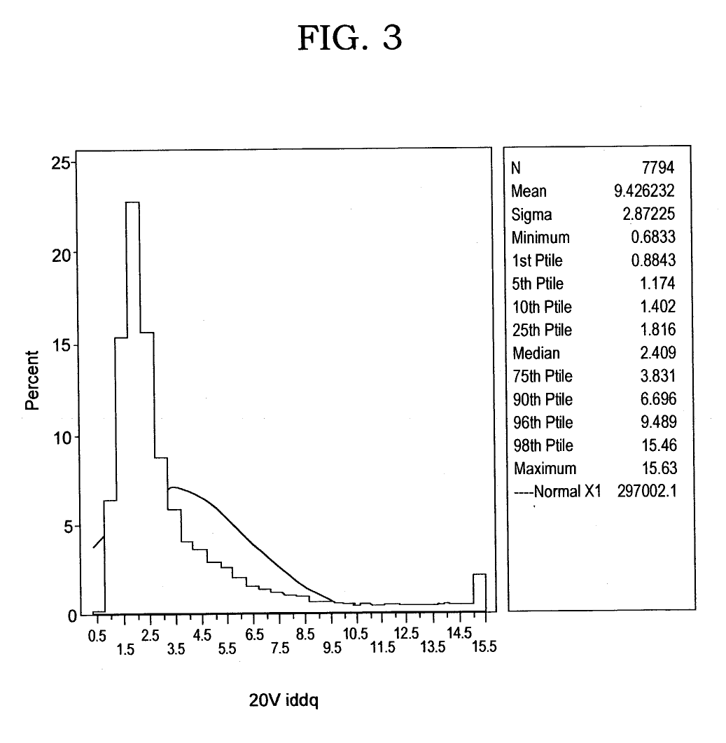

For any one of these types of parametric measurements, the majority of the parts will be located within some type of characteristic distribution. Some, however, will fall outside of this distribution, which indicates that the part has a defect of some type. Empirical study of burn-in fallout of outlier vs. ‘normal’ parts can then be undertaken to determine if or such outlier parts have a higher rate of burn-in fallout. FIG. 3 shows an example of the distribution of I_{ddQ} measurements for a product at a given power supply setting. There is a clear portion of the population bunched up at a low I_{ddQ} reading, but there is a long tail extending out to higher readings. If the outliers turn out to be more likely to become burn-in fails, then a binning method is possible.

6) Other Sorting Algorithms:

An empirical study may be conducted at the burn-in fallout for parts classified with several different sorting algorithms. The algorithms include:

part is located on the edge of the wafer or not

how many surrounding chips are bad

how many chips fail on the same radial line as the die in question

how close is a die to the edge of a wafer

The conclusion reached is that edge die have a higher rate of failure, as do die surrounded by more failing chips.

Applications of Binning for Reliability

Once parts are separated into groups of different reliability by any of the above mentioned means (or any other, for that matter), several applications are possible. Assume that through some type of study of burn-in or field fail results, a determination has been made of the overall population reliability fail rate. Such a rate is commonly referred to in units of ‘fails in time’ (FITS), or parts per million defective per thousand hours of use. An extensive theory and practice exists for such determination. Typically a FIT rate can be given for a population in the cases of:

no burn-in(0% burn in)

100% burn-in at a specific stress condition (usually voltage and temperature)

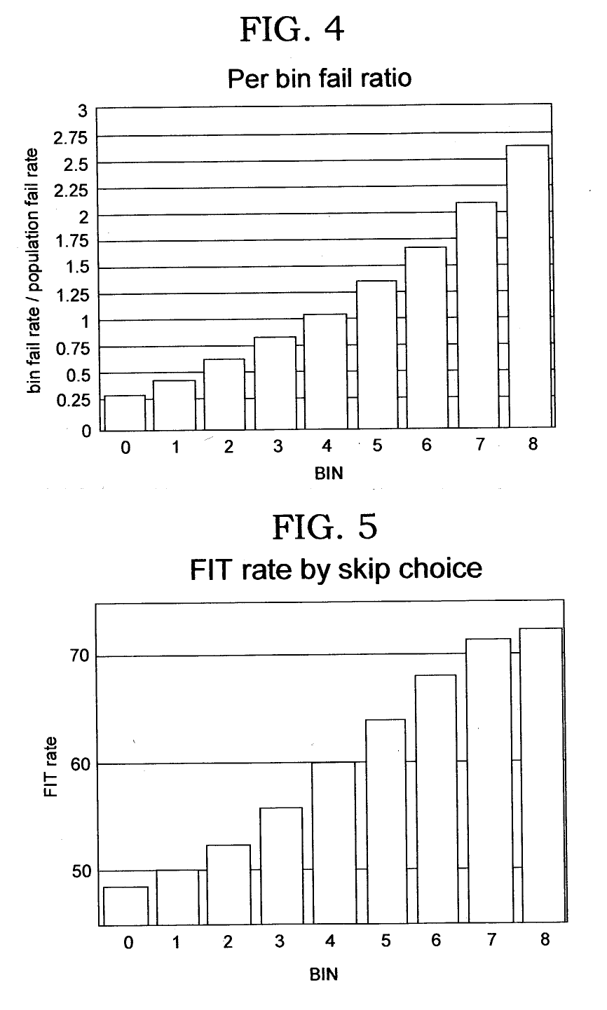

Through statistical binning, we will have separated the parts into N different groups. Each group will fail at some fraction of the overall population fail rate; some will fail at a fraction less than 1, and some greater than 1. Attention is directed to FIG. 4 whis shows: an example from a local region yield analysis. There are 9 bins. Bins 0-3 fail at a rate less than the overall population average, while bins 4-8 fail at a rate above the overall population average. Bin 4 is very close to failing at the same rate as the overall population (close to 1).

Wherein:

F[i]=the ratio of the fail rate of bin 1 to the fail rate of the overall population.

P[i]=the percentage of parts (before burn-in) that are grouped into bin 1.

Pf[i]=the percentage of fails that are grouped into bin i.

N be the number of reliability bin categories.

r100 be the reliability FIT rate for the entire population if burn-in is done.

r0 be the reliability FIT rate for the entire population if burn-in is not done.

Assume the bins are ordered so that bin 1 has the smallest F[i], and bin N the highest.

Then:

N

$${\sum }_{i = 1}^{N} P [ i ] = 1$$

i=1

The fail rate for any individual bin is

R100[i]=F[i]*r100 (if burin is done)

R0[i]=F[i]*r0 (if burn-in is not done)

The fail rate for a grouping of bins from 1 to n where n<=N is

$$\text{(eq 1):}$$

$$\frac{\sum R100 [ i ] * P [ i ]}{\sum P [ i ]}$$

(if burn-in is done . . . sums are from 1 . . . n)

or

$$\text{(eq 2):}$$

$$\frac{\sum R 0 [ i ] * P [ i ]}{\sum P [ i ]}$$

(if burn-in is not done . . . sums are from 1 . . . n)

If burn-in is only done on the worst bins, so that bins 1 through n are skipped, then the overall outgoing fail rate of the population is

$$\text{(eq 3):}$$

$$\frac{\sum P f [ i ]}{100 * ( r 100 - r 0 )} + r 100$$

(sum from i=1 to n)

Given the above relationships, the following applications arise:

1) Skip Plan

Equation 3 gives a reliability fail rate when the best reliability bins are skipped. If r100 is better than the required outgoing fail rate, but r0 is too poor, then one can use a skip plan to burn-in the worst yielding portion of the population and still achieve the required reliability. Here is an illustration of such a skip plan:

FIG. 5 illustrates an example from an actual microprocessor, r100 is 48 FITs and r0 is 72 FITs There are 9 bins (based on local region yield). If 60 FITs is the outgoing reliability requirement, bins 0 through 4 can skip burn-in. In the case-of this product, bins 0 through 4 make up 70% of the parts, so the burn-in savings are substantial.

2) Picking for High Reliability Applications

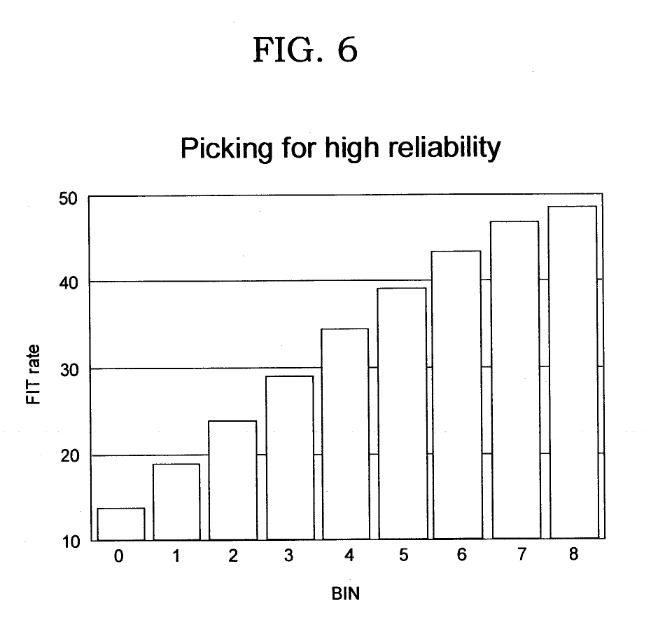

Often times a certain portion of production of a product is targeted for a high reliability application. If the entire population is used to fulfill this application, the burn-in duration required can be excessive. However, if only the best few reliability bins are selected, then a more ‘normal’ burn-in duration can be used. This relation is described in equation 1; a portion of the population can be used to get to a fail rate that is less than r100. Alternatively, if no burn-in is planned, then equation 3 can be used to still pick a portion of the population that will meet a higher reliability requirement than r0. Attention is directed to FIG. 6 which illustrates an application where, r100 is 48 FITs. Bins 0 through 2 can be chosen to achieve a portion of the population with outgoing reliability of 24 FITs (half the fail rate of the overall population).

3) Maverick Screen Improvement

Semiconductor manufacturers often try to improve the overall outgoing quality of their product by screening or scrapping material that appears to have ‘outlier’ characteristics. Yield of wafers is the most common example; if a product is typically yielding 50%, and a small portion (say, 10%) of the wafers are yielding below a limit of, say 15%, then a manufacturer may decide to scrap the good devices from all wafers yielding less than 15%. The methods listed above for separating parts into reliability bins are acting on more ‘direct’ information that just wafer yield, so scrap plans based on these bin methods will do a better job of screening hardware for mavericks.

For example, on the low yielding wafers in the example above, there will probably be some areas of the wafer with good chips that have good reliability indicators (i.e.—they are in a region of high yield, or they do not require array redundancy/repair, etc.). Good die from such areas should not be scrapped. Conversely, there will be good yielding wafers with good die that have indications of poor reliability (i.e.—the chips are in a region of a wafer with poor local region yield, or the chips require a lot of redundancy/repair, etc.). Such chips might be candidates for scrap, or at least more burn-in.

4) Burn-in Optimization

Often times semiconductor manufacturers have limited capability for burn-in of product. In these situations, the critical question is, “What percentage of the population can I burn in?” Binning for reliability helps in this situation by identifying the chips that are most likely to contain reliability defects. If the manufacturer has capacity for burn-in of, say 25% of the product, then one can choose starting with bin N (the least reliable bin) and working down the list until the capacity is consumed. This assures the most optimal use of the limited burn-in resource.

While the invention has been descried in terms of preferred embodiments, those skilled in the art will recognize that the invention can be practiced with modification within the spirit and scope of the appended claims.

What is claimed is:

1. A method of burn-in testing semiconductor wafers with a plurality of dies wherein each die has a plurality of devices comprising:
a) selecting a subset of die to be tested;
b) conducting tests to weed out the highest number of failures; and
c) determining a reliability fail rate to meet a predetermined criteria.

2. The method of claim 1 which includes using empirical correlations in determining the reliability fail rate.

3. The method of claim 2 which includes separating the dies formed to be good into categories with different probabilities of possessing reliability defects.

4. The method of claim 1 wherein the tests include parametric measurements.

5. The method of claim 4 wherein the parametric measurement are based on I_{dd} testing at one or more power supply settings.

6. The method of claim 4 wherein the results of the parametric measurements are used to create a characteristic distribution in determining the fail rate.

7. The method of claim 4 wherein the parametric measurements are based on power supply range of operation in different functional modes.

8. The method of claim 4 wherein the parametric measurements are based on frequency range of operation in different functional modes.

9. The method of claim 4 wherein the parametric measurements are based on temperature range of operation in different functional modes.

10. A method for burn-in testing semiconductor wafers having a plurality of devices on a die comprising:
a) determining an overall population reliability fail rate;
b) separating die into groups of different reliability;
c) selecting a group which meets a predetermined reliability criteria.

11. The method of claim 10 which uses a skip plan.

12. The method of claim 10 which uses a picking for high reliability.

13. The method of claim 10 which uses maverick screen criteria.
